(19) United States
(12) Patent Application Publication
(10) Pub. No.: US 2026/0226653 A1
(43) Pub. Date: Aug. 6, 2026

(54) METHOD FOR PREPARING HIGH-CRYSTALLINE II-V NANOCRYSTAL, II-V NANOCRYSTAL PREPARED THEREBY AND FIELD-EFFECT TRANSISTOR COMPRISING SAME

(71) Applicant: IUCF-HYU (INDUSTRY-UNIVERSITY COOPERATION FOUNDATION HANYANG UNIVERSITY), Seoul (KR)

(72) Inventors: Nuri OH, Suwon-si (KR); Seong Chan KIM, Seoul (KR); Seung Ki SHIN, Seoul (KR); Nam Young GWAK, Seoul (KR); Jae Young SEO, Sejong (KR); Jaeyoung JANG, Seoul (KR); Kyumin LEE, Seoul (KR)

(73) Assignee: IUCF-HYU (INDUSTRY-UNIVERSITY COOPERATION FOUNDATION HANYANG UNIVERSITY), Seoul (KR)

(21) Appl. No.: 19/451,500

(22) Filed: Jan. 16, 2026

Related U.S. Application Data
(63) Continuation of application No. PCT/KR2024/010105, filed on Jul. 15, 2024.

(30) Foreign Application Priority Data
Jul. 19, 2023 (KR) 10-2023-0093975

(51) Int. Cl. C30B 29/10; B82Y 40/00; C30B 7/14; H10D 62/80

(52) U.S. Cl. CPC C30B 29/10; C30B 7/14; H10D 62/80; B82Y 40/00

(57) ABSTRACT

Provided are a method for preparing an II-V group nanocrystal having excellent crystallinity, an II-V group nanocrystal prepared by using the same, and a field-effect transistor comprising the same. By synthesizing an II-V group nanocrystal through a method of using halides of a Group II element and a Group V element as precursors and performing co-reduction, an II-V group nanocrystal can be prepared using stable precursors. In particular, by controlling conditions such as a ratio of the Group II element and the Group V element in the precursors, and a reaction temperature and time after co-reduction, an II-V group nanocrystal satisfying a stoichiometric ratio and having very excellent crystallinity can be prepared, and particle uniformity can be improved. Accordingly, when the II-V group nanocrystal is applied as a p-type semiconductor material of a field-effect transistor, a transistor having excellent electrical performance can be prepared.

### CROSS-REFERENCE TO RELATED APPLICATIONS

This application is a continuation of International Application No. PCT/KR 2024/010105 filed on Jul. 15, 2024, which claims priority to Korean Patent Application No. 10-2023-0093975 filed on Jul. 19, 2023, the entire contents of which are herein incorporated by reference.

### TECHNICAL FIELD

The present invention relates to a method for preparing an II-V group nanocrystal having excellent crystallinity, an II-V group nanocrystal prepared by using the same, and a field-effect transistor comprising the same, and more specifically, relates to a method for preparing a uniform II-V group nanocrystal having excellent crystallinity through a method of using a halide of zinc, which is a Group II element, and a halide of a Group V element as precursors and performing co-reduction, an II-V group nanocrystal prepared by using the same, and a field-effect transistor comprising the same.

### BACKGROUND ART

Zinc pnictide (Zn₃Pn₂) is classified as an II-V group compound formed of zinc (Zn), which is a Group II element, and a pnictogen (Group V) element (Pn=P, As, or Sb), and is known to have characteristics of high carrier mobility and a narrow bandgap. The II-V group compound exhibits p-type characteristics due to defects that facilitate hole formation in a valence band, and a colloidal nanocrystal can be synthesized to have various electrical characteristics and optical characteristics depending on a size thereof. Such II-V group nanocrystals are suitable for large-area processing and can be used in various fields such as energy harvesting and infrared imaging, and thus studies on synthesis of II-V group nanocrystals such as Zn₃As₂ and Zn₃P₂ are being conducted.

For example, Korean Patent Application Publication No. 10-2007-0064554 describes a method for preparing nanoparticles such as Zn₃As₂ by converting precursors containing ions into nanoparticles, and Korean Patent No. 10-1593425 describes a method for preparing zinc arsenide quantum dots by mixing a zinc precursor and a surfactant and heating the same, followed by injecting tris(trimethylsilyl)arsenide as an arsenic precursor into the mixture and growing crystals.

However, zinc has low reactivity and a precursor of a Group V element (in particular, As) has low stability, and thus there has been a limitation in that it is difficult to synthesize II-V group nanocrystals, and even if synthesized, a stoichiometric ratio is not satisfied, resulting in very low crystallinity, and when a cation exchange process is used, a problem arises in that many defects are generated. In addition, when the conventional technologies as described above are used, there has been a problem in that reactivity of a zinc precursor and an arsenic precursor is high, causing oxidation to occur at a surface or crystallinity to be lowered.

Accordingly, there is a need for development of a technology capable of preparing an II-V group nanocrystal having excellent crystallinity while satisfying a stoichiometric ratio with high stability of a precursor, and fabricating a field-effect transistor having excellent electrical characteristics by using the same.

### SUMMARY

### Technical Problem

An object of the present invention is to provide a method for preparing an II-V group nanocrystal having high crystallinity by using a stable precursor.

Another object of the present invention is to provide an II-V group nanocrystal prepared by the method, the II-V group nanocrystal having high crystallinity and a uniform size.

Still another object of the present invention is to provide a field-effect transistor comprising the II-V group nanocrystal and having excellent electrical performance.

### Technical Solution

To achieve the above object, the present invention provides a method for preparing an II-V group nanocrystal, comprising steps of preparing a precursor mixture by mixing a Group II precursor comprising a zinc halide and a Group V precursor comprising a halide of a Group V element; and synthesizing a nanocrystal by adding a reducing agent to the precursor mixture and then performing a co-reduction reaction.

In the present invention, the zinc halide may be at least one selected from the group consisting of zinc chloride (ZnCl₂), zinc iodide (ZnI₂), zinc fluoride (ZnF₂), and zinc bromide (ZnBr₂).

In the present invention, the halide of the Group V element may be at least one selected from the group consisting of arsenic trichloride (AsCl₃), arsenic tribromide (AsBr₃), arsenic triiodide (AsI₃), antimony trichloride (SbCl₃), antimony tribromide (SbBr₃), antimony triiodide (SbI₃), phosphorus trichloride (PCl₃), phosphorus tribromide (PBr₃), and phosphorus triiodide (PI₃).

In the present invention, the Group II precursor and the Group V precursor may each independently further comprise at least one ligand selected from the group consisting of a phosphine-based compound and an amine-based compound.

In the present invention, in the precursor mixture, a molar ratio of zinc to the Group V element may be 1:1 to 8:1.

In the present invention, the reducing agent may comprise at least one selected from the group consisting of lithium triethylborohydride (superhydride), diisobutylaluminium hydride (DIBAL-H), lithium aluminium hydride (LiAlH₄), lithium borohydride (LiBH₄), sodium borohydride (NaBH₄), alane N, N-dimethylethylamine complex (DMEA-AlH₃), and tris(dimethylamino)phosphine.

In the present invention, the co-reduction reaction may be performed at a temperature of 200 to 400° C.

In the present invention, the co-reduction reaction may be performed for 10 to 120 minutes.

The preparation method of the present invention may further comprise, after the co-reduction step, a step of ligand-exchanging a surface of the nanocrystal by using a zinc halide solution.

In the present invention, the step of ligand-exchanging may be performed by mixing the nanocrystal obtained through the co-reduction reaction with a zinc halide and vortexing.

In the present invention, an average particle diameter of the prepared nanocrystal may be 5 to 50 nm.

In the present invention, the II-V group nanocrystal may be a Zn₃As₂ nanocrystal, a Zn₃P₂ nanocrystal, or a Zn₃Sb₂ nanocrystal.

The present invention also provides an II-V group nanocrystal prepared by the above method.

In the present invention, the nanocrystal may comprise a crystalline phase having a space group P4₂/nmc.

The present invention also provides a field-effect transistor comprising an active layer formed using the II-V group nanocrystal.

### Advantageous Effects

In the present invention, by synthesizing an II-V group nanocrystal through a method of using halides of Group II and Group V elements as precursors and performing co-reduction, an II-V group nanocrystal that is difficult to synthesize can be prepared by using stable precursors. In particular, in the present invention, by controlling conditions such as a ratio of the Group II element and the Group V element in the precursor, and a reaction temperature and time after co-reduction, an II-V group nanocrystal satisfying a stoichiometric ratio and having very excellent crystallinity can be prepared, and uniformity of nanocrystal particles can be improved. Accordingly, when the II-V group nanocrystal of the present invention is applied as a p-type semiconductor material of a field-effect transistor, a transistor having excellent electrical performance can be fabricated.

### DESCRIPTION OF DRAWINGS

FIG. 1 schematically illustrates a process for preparing a Zn₃As₂ nanocrystal according to one embodiment of the present invention.

FIG. 2 shows transmission electron microscopy images according to a precursor ratio for the Zn₃As₂ nanocrystal prepared in one embodiment of the present invention.

FIG. 3 shows UV-vis absorption graphs according to a precursor ratio for the Zn₃As₂ nanocrystal prepared in one embodiment of the present invention.

FIGS. 4A and 4B show X-ray diffraction analysis results (A) and results of analyzing enlarged X-ray diffraction peaks (B), respectively, according to a precursor ratio for the Zn₃As₂ nanocrystal prepared in one embodiment of the present invention.

FIGS. 5A and 5B show mapping images (A) of zinc (Zn) and arsenic (As) obtained through energy-dispersive spectroscopy (EDS) and scanning transmission electron microscopy images (B), respectively, for the Zn₃As₂ nanocrystal prepared in one embodiment of the present invention.

FIGS. 6A and 6B show transmission electron microscopy images (A) and absorption graphs (B), respectively, for the Zn₃P₂ nanocrystal prepared in one embodiment of the present invention.

FIGS. 7A and 7B show transmission electron microscopy images (A) and absorption graphs (B), respectively, for the Zn₃Sb₂ nanocrystal prepared in one embodiment of the present invention.

FIGS. 8A, 8B, and 8C show UV-vis absorption graphs (A), absorption graphs (B), and transmission electron microscopy images (C), respectively, according to a reaction temperature for the Zn₃As₂ nanocrystal prepared in one embodiment of the present invention.

FIGS. 9A and 9B show Zn energy levels (A) and As energy levels (B) of X-ray photoelectron spectroscopy analysis according to a precursor ratio for the Zn₃As₂ nanocrystal prepared in one embodiment of the present invention.

FIG. 10 shows results of inductively coupled plasma spectroscopic analysis according to a precursor ratio for the Zn₃As₂ nanocrystal prepared in one embodiment of the present invention.

FIG. 11 shows Fourier transform infrared (FT-IR) analysis results for a Zn₃As₂ nanocrystal prepared in one embodiment of the present invention after ligand exchange.

FIG. 12 schematically illustrates a structure of a field-effect transistor comprising a Zn₃As₂ nanocrystal layer prepared in one embodiment of the present invention.

FIG. 13 shows electrical characteristics of a field-effect transistor prepared in one embodiment of the present invention.

FIGS. 14A, 14B, and 14C show results of output electrical characteristic analysis of nanocrystals ligand-exchanged using ZnCl₂ (A), ZnBr₂ (B), and ZnI₂ (C), respectively, for a field-effect transistor prepared in one embodiment of the present invention.

FIG. 15 shows results of transfer electrical characteristic analysis of ligand-exchanged nanocrystals for a field-effect transistor prepared in one embodiment of the present invention.

### DETAILED DESCRIPTION

Hereinafter, specific embodiments of the present invention will be described in more detail. Unless otherwise defined, all technical and scientific terms used in the present specification have the same meanings as those commonly understood by a person skilled in the technical field to which the present invention pertains. In general, the nomenclature used in the present specification is well known and commonly used in the technical field.

The present invention relates to a method for preparing an II-V group nanocrystal by using a halide of zinc, which is a Group II element, and a halide of a Group V element as a Group II precursor and a Group V precursor, respectively, and performing co-reduction thereof.

In the present invention, by using a ligand complex having excellent stability as a precursor and performing co-reduction, an II-V group nanocrystal that is difficult to synthesize, such as Zn₃As₂, can be prepared by using a precursor having excellent stability, and in particular, by controlling a ratio of the Group II element and the Group V element in the precursor, an II-V group nanocrystal satisfying a stoichiometric ratio can be prepared. In addition, characteristics and uniformity of the nanocrystal can be improved by controlling a reaction temperature and time after co-reduction. As such, according to the present invention, an II-V group nanocrystal having high crystallinity and a uniform size can be prepared through a simple and stable method.

In the present invention, the II-V group nanocrystal is a nanocrystal formed by a combination of a Group II element and a Group V element (pnictogen), wherein the Group II element may be zinc (Zn), and the Group V element may be at least one selected from phosphorus (P), arsenic (As), and antimony (Sb). Specifically, the II-V group nanocrystal may be a Zn₃As₂ nanocrystal, a Zn₃P₂ nanocrystal, or a Zn₃Sb₂ nanocrystal.

In the present invention, the II-V group nanocrystal is prepared by mixing a Group II precursor and a Group V precursor and performing co-reduction using a reducing agent. At this time, the Group II precursor comprises a zinc halide, and the Group V precursor comprises a halide of a Group V element.

In the method for preparing an II-V group nanocrystal according to the present invention, the Group II precursor used may be a complex comprising a halide of zinc, which is a Group II element, and a first ligand, and the Group V precursor may be a complex comprising a halide of a Group V element and a second ligand. In the present invention, by using precursors in the form of such complexes, an II-V group nanocrystal can be prepared using precursors having excellent stability.

Specifically, the zinc halide may comprise a chloride, a bromide, an iodide, a fluoride of zinc, or a combination thereof. For example, the zinc halide may comprise at least one selected from zinc chloride (ZnCl₂), zinc bromide (ZnBr₂), zinc iodide (ZnI₂), and zinc fluoride (ZnF₂).

The Group V element may be a pnictogen element, for example, at least one selected from arsenic (As), antimony (Sb), and phosphorus (P). The halide of the Group V element may comprise a chloride, a bromide, an iodide, a fluoride of the Group V element, or a combination thereof. For example, the halide of the Group V element may comprise at least one selected from arsenic trichloride (AsCl₃), arsenic tribromide (AsBr₃), arsenic triiodide (AsI₃), antimony trichloride (SbCl₃), antimony tribromide (SbBr₃), antimony triiodide (SbI₃), phosphorus trichloride (PCl₃), phosphorus tribromide (PBr₃), and phosphorus triiodide (PI₃).

The first ligand and the second ligand mixed with the Group II element and the Group V element, respectively, may comprise at least one selected from a phosphine-based compound and an amine-based compound, and the ligands comprised in each precursor are independent from each other and may be identical to or different from each other.

In the present invention, the phosphine-based compound may be a phosphine, a phosphine oxide, or a phosphite-based compound in which one or more hydrocarbon groups (R) are bonded to a phosphorus (P) atom. Specifically, the phosphine-based compound may be R₃P, R₂PH, RPH₂, R₃PO, R₂HPO, RH₂PO, R₂POOH, RHPOOH, or RPO(OH)₂, wherein each R is independently a substituted or unsubstituted aliphatic hydrocarbon group having 1 to 40 carbon atoms, or a substituted or unsubstituted aromatic hydrocarbon group having 6 to 40 carbon atoms. For example, the phosphine-based compound may be trioctylphosphine (TOP), trioctylphosphine oxide (TOPO), or diphenylphosphine (DPP).

In the present invention, the amine-based compound is a compound in which one or more hydrocarbon groups (R) are bonded to a nitrogen (N) atom, and may be represented by RNH₂ or R₂NH. Here, each R is independently a substituted or unsubstituted aliphatic hydrocarbon group having 1 to 40 carbon atoms, or a substituted or unsubstituted aromatic hydrocarbon group having 6 to 40 carbon atoms. For example, the amine-based compound may be oleylamine, N, N-diisopropylethylamine, benzylamine, N, N, N′, N′-tetramethylethylenediamine, or triethylamine.

The halide of the Group II element may be dissolved in the first ligand to form a Group II precursor. In the Group II precursor, a concentration of the halide of the Group II element (i.e., zinc halide) may be 0.1 to 10 M, preferably 0.5 to 2 M.

The Group II precursor may be prepared by mixing the halide of the Group II element and the first ligand at 80 to 200° C., preferably 100 to 150° C., and a reaction time during preparation of the precursor may be 12 to 72 hours, preferably 36 to 60 hours.

The halide of the Group V element may be dissolved in the second ligand to form a Group V precursor. In the Group V precursor, a concentration of the halide of the Group V element may be 0.05 to 5 M, preferably 0.1 to 0.5 M.

The Group V precursor may be prepared by mixing the halide of the Group V element and the second ligand at 80 to 180° C., preferably 90 to 120° C., and a reaction time during preparation of the precursor may be 6 to 60 hours, preferably 12 to 36 hours.

In the Group II precursor and the Group V precursor used in the reaction of the present invention, a molar ratio of the Group II element to the Group V element may be 1:1 to 8:1, preferably 2:1 to 6:1, and more preferably 3:1 to 6:1. When a proportion of the Group II element is too low, reactivity of zinc is too low, making it difficult to synthesize a stoichiometric Zn₃Pn₂ nanocrystal and resulting in most of the product existing in an amorphous state; however, when the molar ratio of the Group II element (Zn) to the Group V element is 2:1 or greater, synthesis of a Zn₃Pn₂ nanocrystal is observed, and when the molar ratio is 3:1 or greater, it is more preferable.

In this regard, in Examples of the present invention, Zn₃As₂ nanocrystals were synthesized by respectively adjusting a molar ratio of a Group II element (Zn) and a Group V element (As) in a precursor to 1:1, 2:1, 3:1, and 4:1, and as a result, it was confirmed that, when the molar ratio was 4:1, an elemental ratio of Zn and As in the synthesized nanocrystals was approximately 3:2 and close to a stoichiometric ratio. From this aspect, the molar ratio of the Group II element and the Group V element is preferably 3:1 to 6:1, more preferably 4:1 to 6:1, and specifically may be 4:1 to 5:1.

In addition, in Examples of the present invention, even when phosphorus (P) or antimony (Sb) was used as the Group V element, nanocrystals were synthesized by respectively adjusting the molar ratio of Zn and the Group V element to 2:1, 4:1, and 6:1, and it was confirmed that, when the ratio was 4:1 or greater, scattering due to an amorphous surface did not occur. From this aspect, the molar ratio of the Group II element and the Group V element is preferably 3:1 to 6:1, and specifically may be 4:1 to 6:1.

In the method of the present invention, the Group II precursor and the Group V precursor are co-reduced using a reducing agent. In the present invention, an II-V group nanocrystal having excellent crystallinity can be synthesized through a simple method of using precursors having excellent stability and co-reducing the same as described above.

In the present invention, the reducing agent may comprise at least one selected from the group consisting of lithium triethylborohydride (superhydride), diisobutylaluminium hydride (DIBAL-H), lithium aluminium hydride (LiAlH₄), lithium borohydride (LiBH₄), sodium borohydride (NaBH₄), alane N, N-dimethylethylamine complex (DMEA-AlH₃), and tris(dimethylamino)phosphine, and preferably may comprise a hydride-based reducing agent.

The reducing agent may be used by dissolving the same in an organic solvent. For example, as the solvent, at least one selected from dioctylether, octadecene, trioctylamine, and tetrahydrofuran may be used.

The step of synthesizing the II-V nanocrystals may be performed by mixing the Group II precursor and the Group V precursor, adding the reducing agent, and reacting at a high temperature. The reaction may be performed by colloidal nanocrystal synthesis using heating-up, hot injection, or the like.

Specifically, the reaction may be performed at a temperature of 150° C. or higher, for example, 200 to 400° C. Preferably, the reaction may be performed at 250 to 350° C., and more preferably at 280 to 320° C. In this regard, in Examples of the present invention, nanocrystals were synthesized by respectively adjusting the reaction temperature to 200, 220, 240, 260, 280, and 300° C. and absorbance was measured, and as a result, it was confirmed that a rapid increase in absorbance was observed at 280° C., and absorbance was highest when nanocrystals were synthesized at 300° C.

In addition, the reaction may be performed for 10 to 120 minutes, preferably 20 to 90 minutes. More preferably, the reaction may be performed for 30 to 60 minutes. In this regard, in Examples of the present invention, it was confirmed that, when the reaction time was too short as 10 minutes, aggregation of particles occurred, whereas when the reaction was performed for 30 minutes or longer, dispersibility was improved and particles having a uniform size were synthesized.

In one embodiment of the present invention, after completion of the reaction, nanocrystals may be obtained by further performing, as necessary, a cooling step; a purification step; a washing step; and/or a centrifugation step.

The crystals obtained according to the present invention may be nanocrystals having an average size (particle diameter) of 5 to 50 nm, preferably 6 to 20 nm, and comprising a crystalline phase having a space group P4₂/nmc. In general, bulk II-V group crystals exhibit various forms including α, α′, and β phases; however, the II-V group crystals of the present invention have a nanocrystal form having an α″ phase with a space group of P4₂/nmc.

As such, by using the present invention, II-V group nanocrystals having excellent crystallinity, a pseudo-face-centered cubic crystal structure due to the α″ phase, and uniform distribution of Zn and As can be prepared. In addition, crystallinity and stability of the synthesized nanocrystals can be further improved by controlling a precursor ratio and a reaction temperature.

In one embodiment of the present invention, the nanocrystals may be surface-treated using solution-phase ligand exchange, solid-state ligand exchange, or the like. According to the ligand exchange, electrical characteristics of the nanocrystals can be improved, and preferably, solution-phase ligand exchange may be used.

A zinc halide may be used for the ligand exchange, and for example, at least one selected from zinc chloride (ZnCl₂), zinc bromide (ZnBr₂), and zinc iodide (ZnI₂) may be used. In particular, from the viewpoint of electrical characteristics of the nanocrystals, it is preferable to perform ligand exchange with zinc bromide (ZnBr₂) or zinc iodide (ZnI₂), and zinc iodide (ZnI₂) may be more preferably used.

A solvent used for the ligand exchange may comprise at least one selected from dimethylformamide (N, N-dimethylformamide), formamide, and N-methylformamide.

The ligand exchange step may be performed by mixing the nanocrystal solution and the zinc halide solution.

In an exemplary embodiment of the present invention, a concentration of the nanocrystal solution may be 10 to 100 mg/mL, preferably 30 to 50 mg/mL, and a concentration of the zinc halide solution may be 0.01 to 2 M, preferably 0.05 to 0.5 M. In this case, the nanocrystal solution and the zinc halide solution may be mixed at a volume ratio of 1:1 to 1:10.

After mixing the nanocrystal solution and the zinc halide solution, ligands on a surface may be exchanged by vortexing. For sufficient ligand exchange, the vortexing step may be performed for 10 seconds to 10 minutes, preferably 1 to 5 minutes.

After performing the ligand exchange step, ligand-exchanged nanocrystals may be obtained by further performing, as necessary, a purification step; a washing step; and/or a centrifugation step.

As such, by performing the ligand exchange step on the II-V group nanocrystals, hole mobility of the synthesized nanocrystals can be improved, and the nanocrystals can be applied to a field-effect transistor device to prepare a p-type semiconductor device.

Accordingly, the present invention can also provide a device comprising the II-V group nanocrystals, preferably a field-effect transistor.

A field-effect transistor (FET) is a transistor that controls current of source and drain electrodes by using a principle in which a gate through which electrons or holes flow is generated by an electric field of a channel by applying a voltage to a gate electrode. The II-V group nanocrystals of the present invention exhibit p-type semiconductor characteristics and have excellent crystallinity and electrical characteristics, and thus can provide a field-effect transistor having excellent output characteristics.

Specifically, the device of the present invention may comprise the II-V group nanocrystal layer as an active layer.

The nanocrystal layer serves as an active layer of the device and may be formed by coating the II-V group nanocrystals of the present invention through a solution process. The coating may be performed by using spin coating, drop coating, self-assembly coating, layer-by-layer coating, or the like.

As a solvent of a nanocrystal coating solution, at least one selected from dimethylformamide, octane, 1,2-ethanedithiol (EDT), sodium sulfide, sodium azide, 1-octanethiol, thiourea, diethyl zinc, and the like may be used. A concentration of the nanocrystal coating solution may be, for example, 10 to 100 mg/mL, but is not limited thereto.

After coating the nanocrystal coating solution, a nanocrystal layer may be formed by heat-treating at a temperature of 150 to 400° C. for 10 to 60 minutes.

In the present invention, a thickness of the nanocrystal layer may vary depending on a type of the device and desired performance, and may be, for example, 5 nm to 100 μm, preferably 10 nm to 10 μm, and specifically within a range of 100 nm to 1 μm.

In the present invention, the device may further comprise components necessary for the device, such as a substrate, one or more electrodes, an electron transport layer, a hole transport layer, and a hole injection layer.

In the present invention, the electrodes may be formed of a metal, a conductive oxide, or a conductive polymer, and for example, metals such as Au, Ag, Pt, and Cu, or conductive oxides such as ITO (indium tin oxide), FTO (fluorine-doped tin oxide), IZO (indium zinc oxide), AZO (aluminium-doped zinc oxide), and GZO (gallium zinc oxide) may be used, but are not limited thereto.

As an electron transport material forming the electron transport layer, known metal oxides may be applied. Such metal oxides may be materials in which fluorine is doped or bonded to metals such as Al, Cd, Cs, Cu, Ga, Ge, In, and Li, or titanium dioxide (TiO₂), zinc oxide (ZnO), zirconium oxide (ZrO), tin oxide (SnO₂), tungsten oxide (WO₃), tantalum oxide (Ta₂O₃), and the like, which are doped or not doped with Al, Mg, In, Li, Ga, Cd, Cs, Cu, and the like, but are not limited thereto.

As a hole transport material forming the hole transport layer, TFB (poly[(9,9-dioctylfluorenyl-2,7-diyl)-co-(4,4′-(N-(p-butylphenyl))diphenylamine)]), CBP (4,4′-N, N′-dicarbazolyl-biphenyl), polyaniline, polypyrrole, and the like may be used, but are not limited thereto.

As a hole injection material forming the hole injection layer, at least one selected from PEDOT: PSS (poly(ethylenedioxy)thiophene): polystyrene sulfonate), PEDOT (poly(ethylenedioxy)thiophene), polyaniline, polypyrrole, polythiophene, polyacetylene, polyphenylene, and the like may be used, but are not limited thereto.

The nanocrystal layer used as the active layer in the device of the present invention comprises the II-V group nanocrystals of the present invention, exhibits p-type semiconductor characteristics, and has excellent crystallinity and electrical characteristics, and advantages such as high mobility and a narrow bandgap, which are characteristics of II-V group semiconductor compounds. Accordingly, the II-V group nanocrystals of the present invention can be usefully applied to an active layer of a field-effect transistor device.

### EXAMPLES

Hereinafter, the present invention will be described in more detail through Examples. However, these Examples are provided to illustratively describe the present invention by presenting some experimental methods and compositions, and the scope of the present invention is not limited to these Examples.

### Preparation Example 1: Synthesis of Zn₃As₂ Nanocrystals Using a Co-Reduction Method

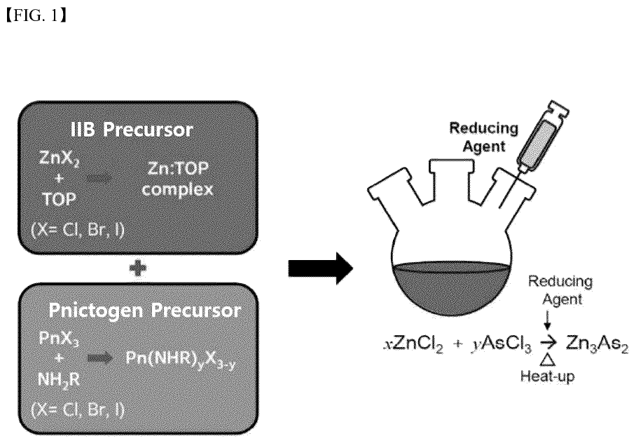

As shown in FIG. 1, Zn₃As₂ nanocrystals were synthesized by co-reducing a zinc precursor and a pnictogen (Group 15) precursor.

For the zinc precursor, ZnCl₂, which is a zinc halide material, and trioctylphosphine (TOP) were mixed and stirred for 48 hours on a hot plate at 120° C. to prepare a precursor at a concentration of 1 M. For the pnictogen precursor, a precursor at a concentration of 0.25 M was prepared by reacting AsCl₃ with degassed oleylamine on a hot plate at 100° C. for 24 hours. In addition, as a reducing agent, 2 M lithium triethylborohydride (super-hydride, SH) was prepared using degassed dioctyl ether (DOE). In this experiment, synthesis of all precursors was performed in a glovebox.

In order to synthesize Zn₃As₂ nanocrystals, which are an II-V group semiconductor compound, 10 mL of degassed oleylamine and 1 mL each of the zinc precursor and the pnictogen precursor were loaded into a 50 mL three-neck flask. Under a nitrogen atmosphere, 1.25 mL of lithium triethylborohydride (SH) as a reducing agent was added and co-reduction was performed, followed by heating to a temperature of 300° C. and growing for 1 hour to synthesize nanocrystals.

Based on the above experimental method, nanocrystals were synthesized by respectively adjusting a molar ratio of Zn and As in the precursors to 1:1, 2:1, 3:1, and 4:1, and were used in experiments.

### Experimental Example 1: TEM Image Analysis of Zn₃As₂ Nanocrystals According to a Zn/As Ratio

Based on the method of Preparation Example 1, nanocrystals were synthesized by respectively adjusting a Zn:As ratio to 1:1, 2:1, 3:1, and 4:1, and transmission electron microscopy (TEM) images of each nanocrystal were analyzed.

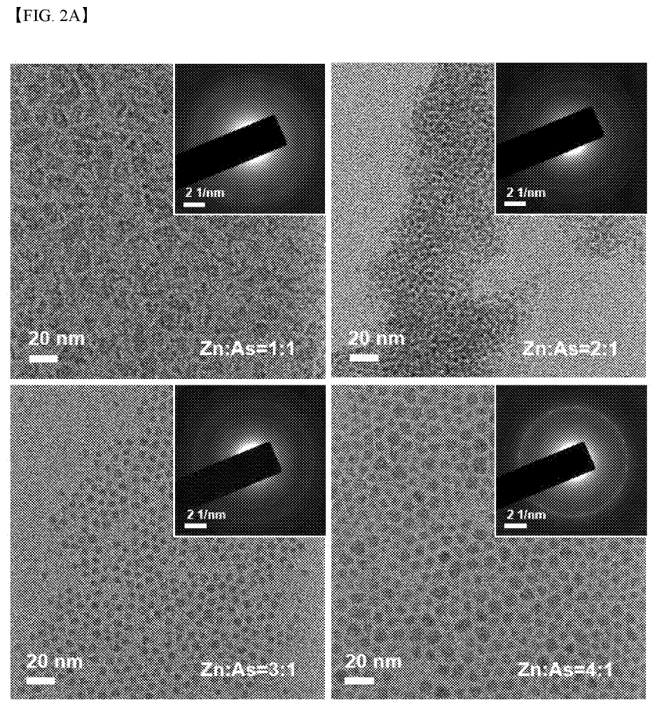

FIG. 2 shows TEM images of the nanocrystals, and when the Zn/As ratio was low as 1 or 2, a size of the nanocrystals was non-uniform, an amorphous surface was exhibited, and a tendency to aggregate in a non-crystalline state was exhibited. In contrast, when the ratio of the Zn precursor was excessive as 3 or 4, a SAED pattern was clearly observed, and it was confirmed that nanocrystals having uniform average sizes of 6.35±0.49 nm and 10.77±1.06 nm were synthesized.

### Experimental Example 2: UV-vis Absorption Analysis of Zn₃As₂ Nanocrystals According to a Zn/As Ratio

Based on the method of Preparation Example 1, nanocrystals were synthesized by respectively adjusting a molar ratio of Zn:As to 1:1, 2:1, 3:1, and 4:1, and ultraviolet-visible spectroscopy analysis was performed for each nanocrystal. The ultraviolet-visible spectroscopy spectrum was recorded at 200 to 1400 nm using a SHIMADZU UV-2600 UV-vis spectrophotometer.

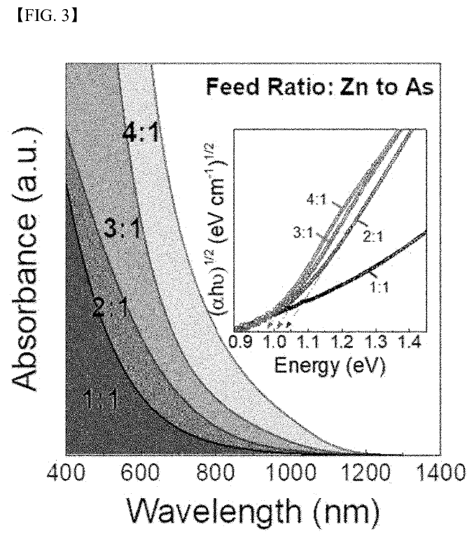

FIG. 3 shows UV-vis absorption graphs of the nanocrystals, and as the Zn/As ratio increased, a red shift in an absorption spectrum was observed. In addition, according to a Tauc plot, it can be confirmed that a size of the nanocrystals increased when the Zn/As ratio increased. However, when the Zn/As ratio was 1, severe scattering occurred due to an amorphous surface of the nanocrystals.

Accordingly, when Zn₃As₂ nanocrystals are prepared by the method of the present invention, it can be confirmed that it is preferable that the Zn/As ratio is at least 2 or greater.

### Experimental Example 3: Analysis of X-Ray Diffraction Results of Zn₃As₂ Nanocrystals According to a Zn/As Ratio

Based on the method of Preparation Example 1, nanocrystals were synthesized by respectively adjusting a Zn:As ratio to 1:1, 2:1, 3:1, and 4:1, and X-ray diffraction (XRD) analysis was performed for each nanocrystal using a miniFlex 600 diffractometer (RIGAKU).

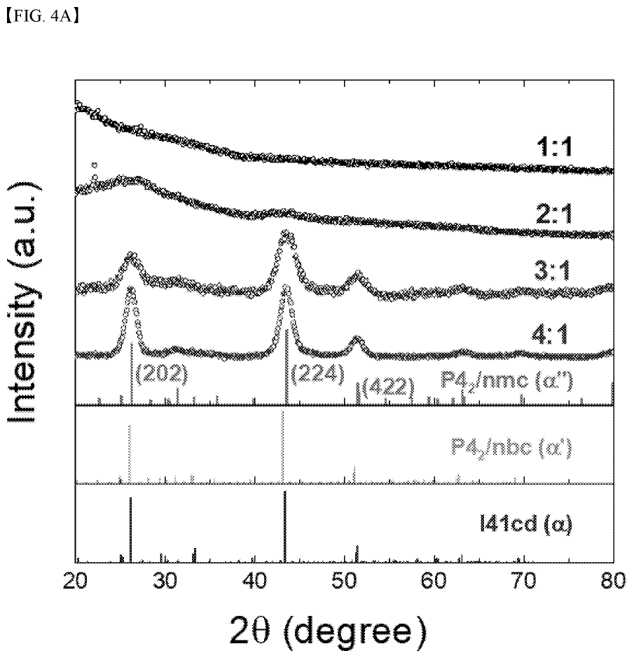

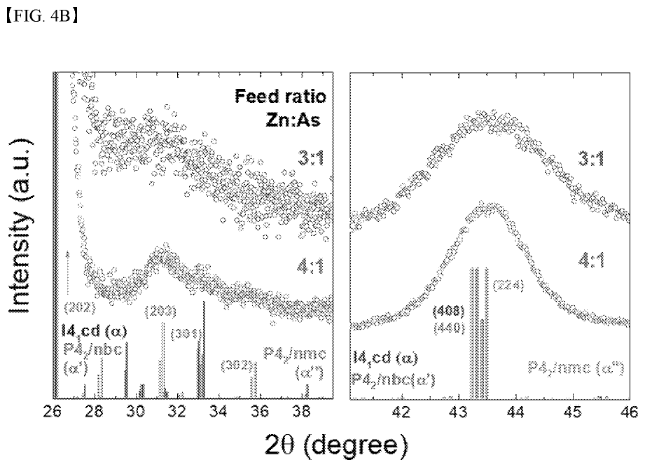

FIGS. 4A and 4B show X-ray diffraction analysis result graphs (A) and enlarged graphs (B) of the nanocrystals, and when the Zn/As ratio was 2 or less, it can be confirmed that an XRD pattern of the nanocrystals was broad and crystallinity was not good. In contrast, when the Zn/As ratio was 3 or greater, crystallinity increased, and peaks at 26.2° and 43.5° matched (202) and (224) of a tetragonal structure.

Bulk Zn₃As₂ generally exhibits various forms including α, α′, and β phases, wherein an α phase generally has an I4₁cd structure and an α′ phase has a P4₂/nbc structure. However, two XRD patterns for the α and α′ phases did not match the nanocrystals of the present invention, and it was confirmed that nanocrystals having a Zn/As ratio of 3 or 4 exhibited a P4₂/nmc structure of an α″ phase.

According to these results, it can be confirmed that it is preferable that a Zn/As ratio is 3 or greater in preparation of Zn₃As₂ nanocrystals of the present invention.

### Experimental Example 4: HAADF-STEM Image and EDS Mapping Image Analysis of Zn₃As₂ Nanocrystals

Nanocrystals were synthesized with a Zn/As ratio of 4 in Preparation Example 1, and high-angle annular dark-field scanning transmission electron microscopy (HAADF-STEM) images were obtained for the synthesized Zn₃As₂ nanocrystals.

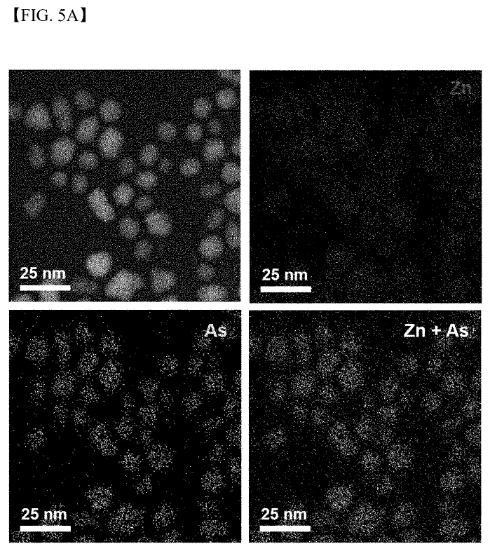

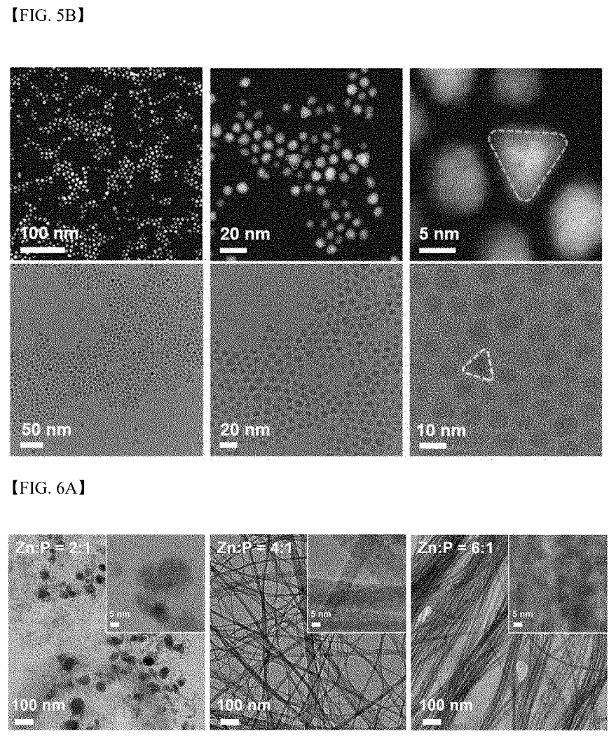

Mapping images of zinc (Zn) and arsenic (As) obtained through energy-dispersive spectroscopy (EDS) are shown in FIG. 5A, and scanning transmission electron microscopy (STEM) images of the nanocrystals are shown in FIG. 5B.

Referring to the images of the nanocrystals, it can be confirmed that facets were developed and crystallinity was high in Zn₃As₂ nanocrystals having a Zn/As ratio of 4. In addition, presence or absence of Zn, As, Cl, and P elements in the Zn₃As₂ nanocrystals was confirmed through EDS, and a triangular shape was observed in the Zn₃As₂ nanocrystals due to an α″-phase, thereby confirming a pseudo-face-centered cubic crystal structure.

As a result, it was observed that Zn and As were uniformly distributed even if sizes of the nanocrystals were diverse, and it can be confirmed that Cl and P were not involved in synthesis of the nanocrystals.

### Experimental Example 5: Characterization Analysis of Zn₃P₂ and Zn₃Sb₂ Nanocrystals

Using the method of Preparation Example 1, Zn₃P₂ and Zn₃Sb₂ nanocrystals were synthesized by using a P precursor or an Sb precursor instead of an As precursor as a pnictogen precursor.

For Zn₃P₂, as a P precursor, one obtained by reacting PCl₃ with degassed oleylamine on a hot plate at 100° C. for 24 hours was used, and for Zn₃Sb₂, as an Sb precursor, one obtained by reacting SbCl₃ with degassed oleylamine on a hot plate at 100° C. for 24 hours was used. Based on the above method, nanocrystals were synthesized by respectively adjusting a molar ratio of Zn to P or Sb in the precursors to 2:1, 4:1, and 6:1.

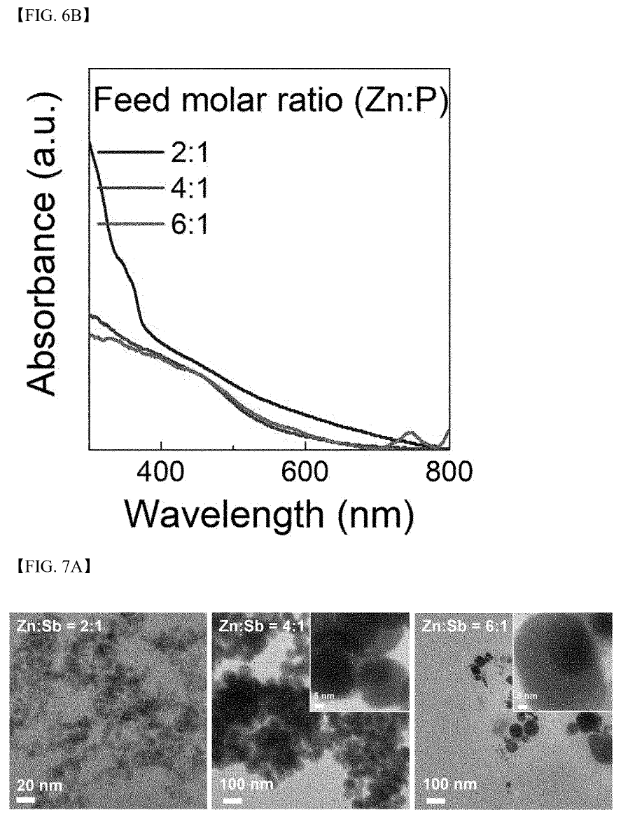

FIGS. 6A and 6B show TEM images (A) and absorbance graphs (B) of Zn₃P₂ nanocrystals, respectively. As a result, it can be confirmed that nanowires were formed when a Zn ratio in Zn₃P₂ was 4 or greater, and lattice fringes were observed at high magnification.

In addition, referring to the absorbance graphs, when the Zn/P ratio was 2, severe scattering occurred due to an amorphous surface of the nanocrystals, and from this, it can be understood that it is preferable that the Zn/P ratio is 4 or greater.

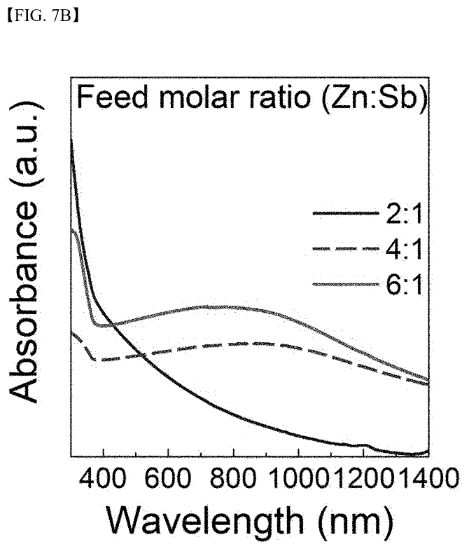

FIGS. 7A and 7B show TEM images (A) and absorbance graphs (B) of Zn₃Sb₂ nanocrystals, respectively. Referring to the experimental results, it can be confirmed that relatively large particles were formed when a Zn ratio in Zn₃Sb₂ was 4 or greater, and lattice fringes were observed at high magnification. In addition, in the case of rectangular Zn₃Sb₂, it was confirmed that the nanocrystals had a hexagonal structure as a result of lattice fringe measurement.

Referring to absorbance graphs of Zn₃Sb₂ nanocrystals, when the Zn/Sb ratio was 2, severe scattering occurred due to an amorphous surface of the nanocrystals, and it can be understood that smaller particles were formed compared to the case where the Zn/Sb ratio was 4 or greater.

### Experimental Example 6: Confirmation of Characteristics of Zn₃As₂ Nanocrystals According to a Synthesis Temperature and a Growth Time

Nanocrystals were prepared by the method of Preparation Example 1 with a Zn/As ratio of 4, while performing synthesis by increasing a synthesis temperature by 20° C. in a range of 200 to 300° C. and preparing solutions of nanocrystals. For each synthesized nanocrystal, ultraviolet-visible spectroscopy analysis was performed, and crystal shapes were confirmed by TEM images.

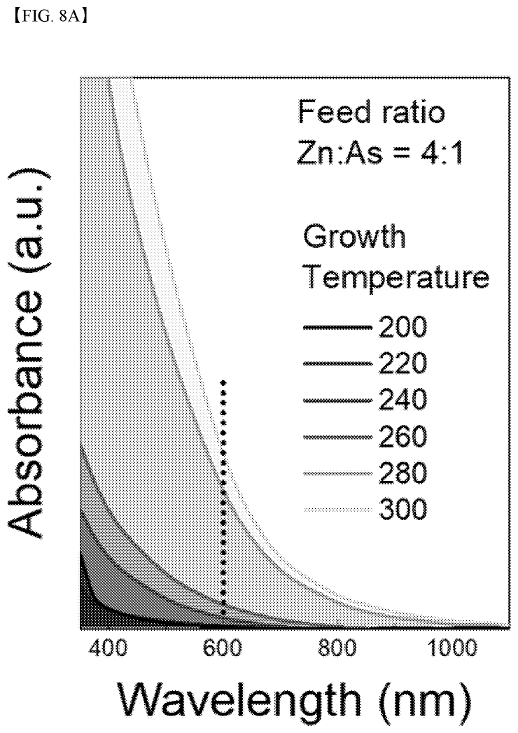

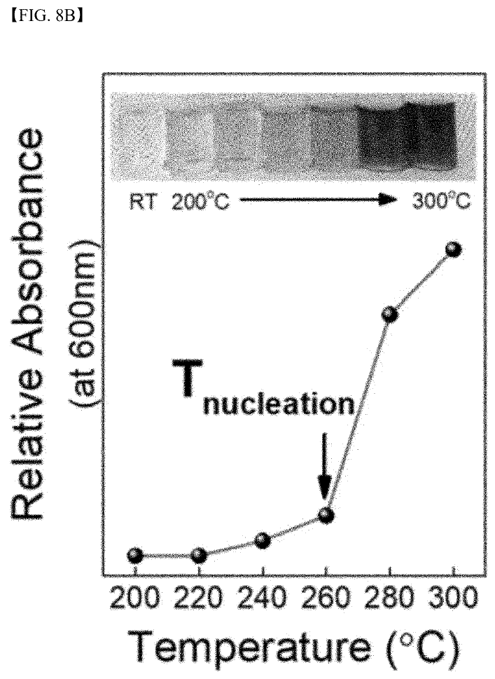

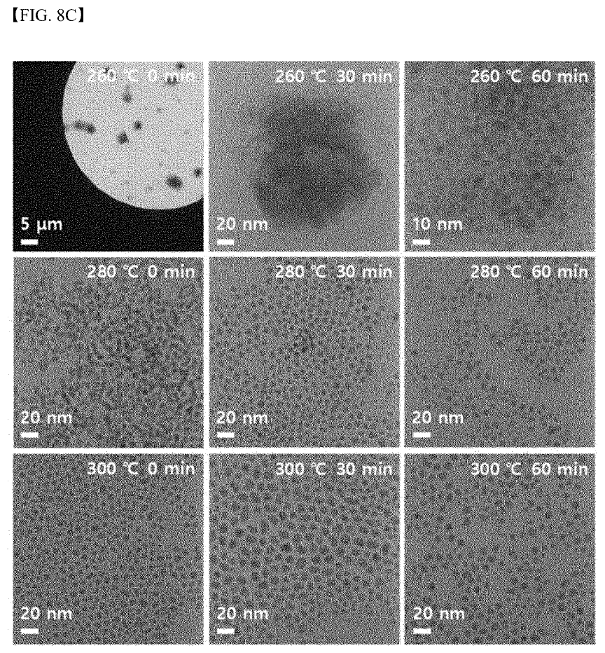

FIG. 8A shows UV-vis absorption graphs of nanocrystals at each temperature, and as the Zn/As ratio and the reaction temperature increased, a red shift in an absorption spectrum was observed, but absorption peaks did not appear. From this, it was inferred that the nanocrystals of the present invention were larger in size than conventional quantum dots and did not exhibit quantum confinement effects, and thus had no absorption peaks.

FIG. 8B is a graph showing photographs of nanocrystal solutions according to a reaction temperature and absorbance at 600 nm, and it was confirmed that, at low temperatures of 200 to 240° C., there was almost no change in absorbance and the solutions were light beige, whereas nucleation started at 260° C. and the solutions were dark brown. In addition, a rapid increase in absorbance was observed at 280° C., and absorbance was highest when nanocrystals were synthesized at 300° C.

FIG. 8C shows TEM images of nanocrystals according to temperature and time, and when grown for 30 minutes at 260° C., nanocrystals remained in a cluster form, and after growth for 1 hour, relatively larger particles having a size of 6 nm were formed. At 280° C., synthesized nanoparticles were aggregated, but as time elapsed, dispersibility was improved and particles having a uniform size were synthesized. When synthesized at 300° C., an increase in particle size was observed from an initial stage, and it was confirmed that a triangular shape was developed as the growth time increased.

Accordingly, it can be confirmed that 300° C. is most suitable as a reaction temperature, and it is preferable that a reaction time is 30 minutes or longer.

### Experimental Example 7: XPS Result Analysis of Zn₃As₂ Nanocrystals According to a Zn/As Ratio

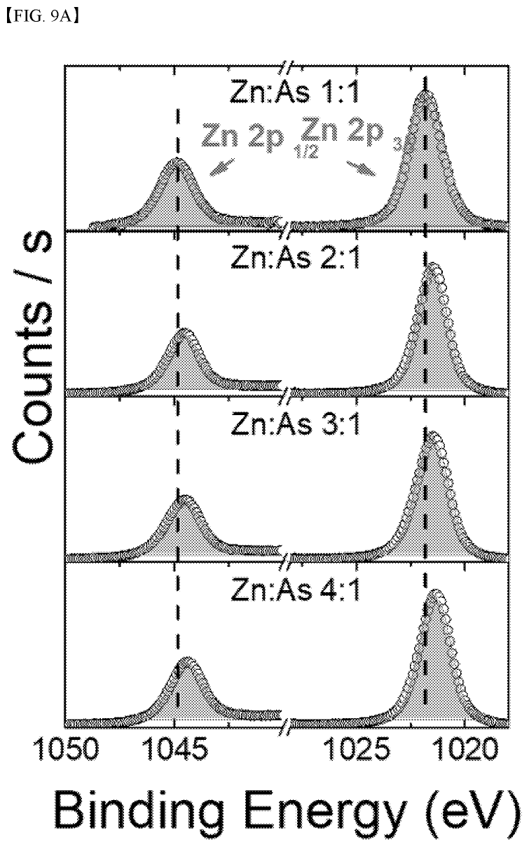

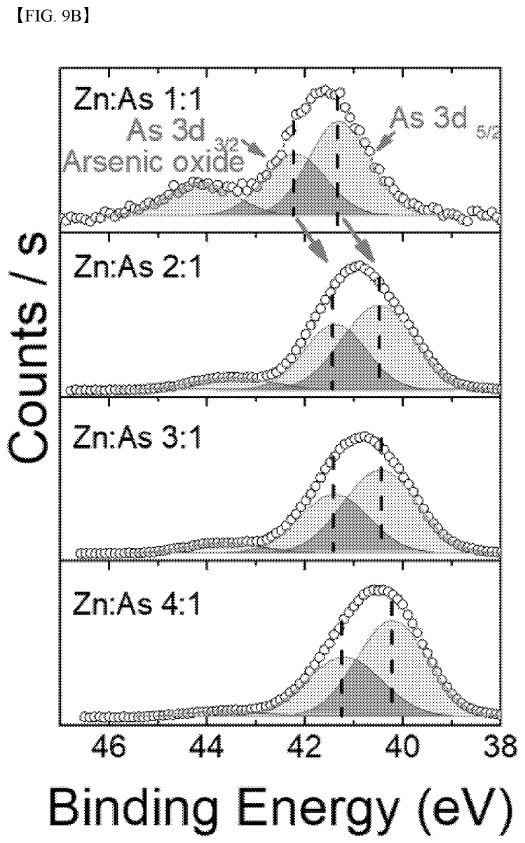

Based on the method of Preparation Example 1, nanocrystals were synthesized by respectively adjusting a Zn:As ratio to 1:1, 2:1, 3:1, and 4:1, and Zn energy levels (A) and As energy levels (B) were analyzed through X-ray photoelectron spectroscopy (XPS) for each nanocrystal and are shown in FIGS. 9A and 9B, respectively.

As a result, as an amount of the Zn precursor increased, changes in which binding energies decreased were observed at a Zn 2 p level and an As 3 d level. In particular, Zn 2 p ½ and 2 p 3/2 levels shifted from 1045 eV to 1044.3 eV and from 1021.8 eV to 1021.4 eV, respectively. Similarly, As 3 d ⅔ and 3 d 5/2 levels showed similar tendencies, shifting from 42.2 eV to 41.2 eV and from 41.3 eV to 40.3 eV, respectively.

In addition, in nanocrystals synthesized with a Zn/As ratio of 1, a peak near 44.1 eV related to an As—O bond peak was observed. However, as a content of the Zn precursor increased, a peak of arsenic oxidation decreased. This is because reactivity of zinc is relatively low, making it difficult for all zinc precursors to participate in the synthesis reaction, and as a result, arsenic having high oxygen affinity becomes abundant on surfaces of the nanocrystals and is easily oxidized, resulting in an amorphous unstable structure. Consequently, significant changes in XPS results were confirmed due to surface oxidation.

Accordingly, when a Zn ratio is too low, crystallinity is low and a degree of surface oxidation is high, whereas when the Zn/As ratio was increased to 3 or greater, it was confirmed that crystallinity was excellent.

### Experimental Example 8: ICP-OES Result Analysis of Zn₃As₂ Nanocrystals According to a Zn/As Ratio

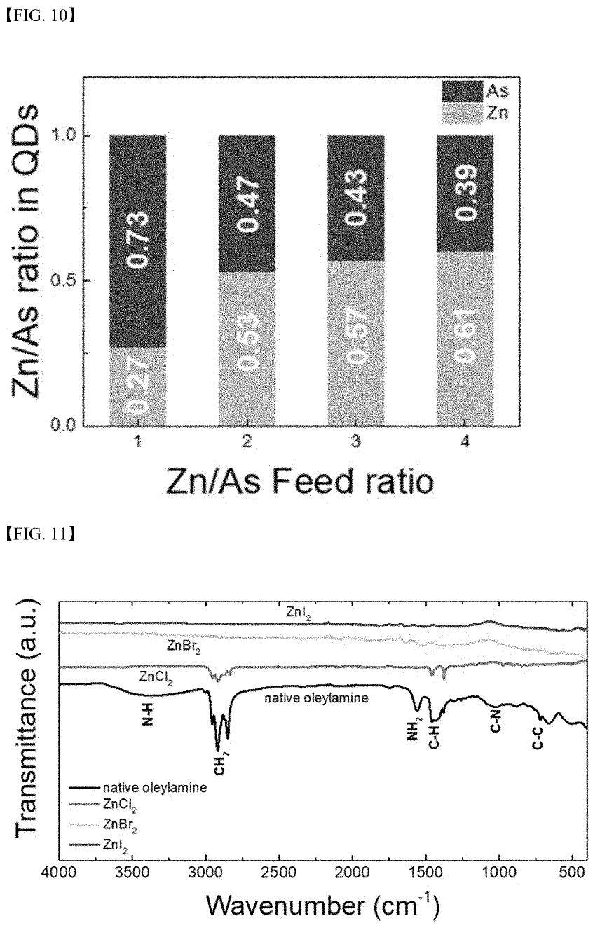

Based on the method of Preparation Example 1, nanocrystals were synthesized by respectively adjusting a Zn:As ratio to 1:1, 2:1, 3:1, and 4:1. Results of inductively coupled plasma optical emission spectrometry (ICP-OES) for the synthesized nanocrystals are shown in FIG. 10.

As a result, in nanocrystals synthesized with a Zn/As ratio of 1, an amount of detected arsenic was at least twice that of zinc, and it can be confirmed that arsenic was abundant on a surface and ZnₓAs_{y} mixed in the nanocrystals was present.

Meanwhile, as a concentration of zinc increased, an amount of detected zinc also increased, and in particular, when the Zn/As ratio was 4, atomic concentrations of Zn and As were calculated as 61% and 39%, respectively. The values are very close to an ideal stoichiometric ratio of 3:2, and it can be understood that almost all As was consumed when the Zn/As ratio was 4.

That is, due to low reactivity of zinc, when the Zn/As ratio is less than 2, nanocrystals having a significant amount in an amorphous state are synthesized, whereas when the ratio was increased to 4, it can be confirmed that nanocrystals mostly comprising Zn₃As₂ were synthesized.

### Preparation Example 2: Preparation of Nanocrystals Ligand-Exchanged With a Zinc Halide

The nanocrystals prepared according to Preparation Example 1 were dispersed in octane at a concentration of 50 mg/mL, and solution-phase ligand exchange was performed using zinc halide inorganics ZnCl₂, ZnBr₂, and ZnI₂, respectively.

As a solution used for the ligand exchange, a solution in which 0.5 mmol of a zinc halide, 0.3 mmol of ammonium acetate, and 5 mL of dimethylformamide were mixed was used. After adding 5 mL of the zinc solution, 5 mL of octane, and 1 mL of the nanocrystal solution, ligand exchange was performed by vortexing for 1 minute. Toluene was added to the exchanged solution to precipitate, and then the ligand-exchanged nanocrystals were dispersed in dimethylformamide at 50 mg/mL.

### Experimental Example 9: FT-IR Analysis of Zinc Halide-Exchanged Zn₃As₂ Nanocrystals

Solution-phase ligand exchange was performed on Zn₃As₂ nanocrystals using zinc halide-based inorganics (ZnCl₂, ZnBr₂, and ZnI₂) according to Preparation Example 2, and Fourier transform infrared spectroscopy (FT-IR) was performed for each nanocrystal.

FIG. 11 shows FT-IR analysis results for each nanocrystal, and it was shown that peaks (1570 cm⁻¹ and 3358 cm⁻¹) generated from an NH bond of oleylamine disappeared after ligand exchange. From this, it could be confirmed that oleylamine was replaced with the zinc halide material in the solution ligand exchange process, and thus oleylamine was not present on surfaces of the nanocrystals.

### Preparation Example 3: Preparation of a Field-Effect Transistor Using Zn₃As₂ Nanocrystals

The ligand-exchanged Zn₃As₂ nanocrystal solution of Preparation Example 2 was spin-coated on a SiO₂ substrate deposited to 300 nm to form a thin film. After baking the thin-film nanocrystal layer at 250° C. for 30 minutes, gold (Au) was deposited as electrodes to fabricate a field-effect transistor (FET).

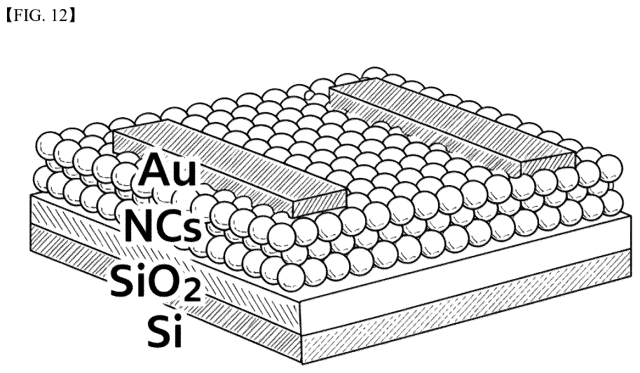

FIG. 12 schematically illustrates a structure of the prepared field-effect transistor. Referring to FIG. 12, the prepared field-effect transistor has a structure in which an insulating layer and a nanocrystal layer are formed on a substrate and electrodes (gold) are formed.

### Experimental Example 10: Evaluation of Electrical Characteristics of the Field-Effect Transistor

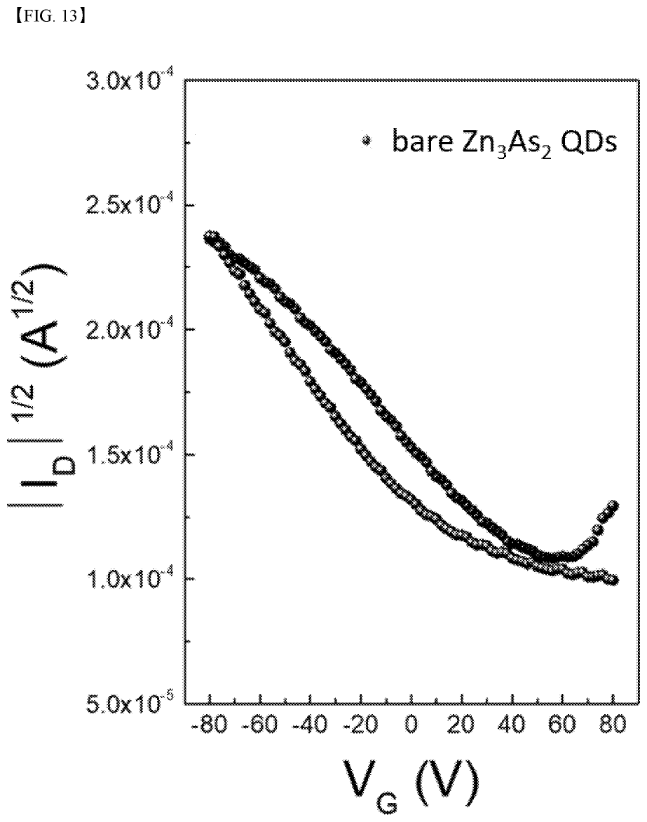

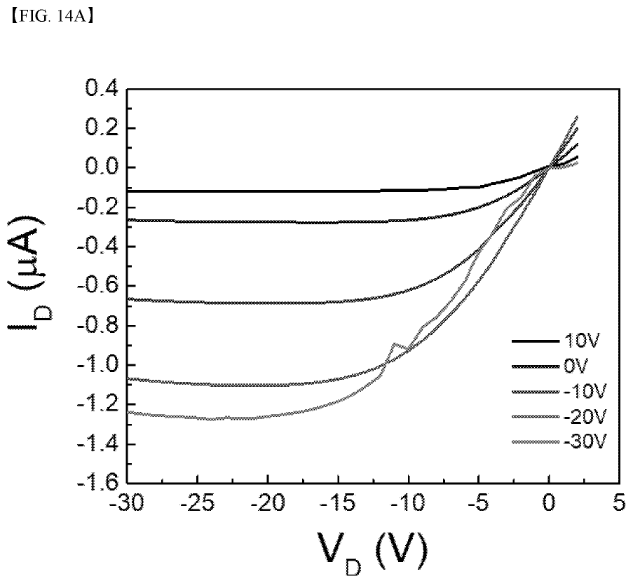

Results of evaluating electrical characteristics of the field-effect transistor prepared according to Preparation Example 3 are shown in FIG. 13. In addition, electrical characteristics of a field-effect transistor prepared using the nanocrystals of Preparation Example 1 without performing ligand exchange were also evaluated, and the results were compared.

As a result, p-type characteristics were observed in the nanocrystals at a bias of −80 V. In addition, even when ligand exchange was not performed, sufficient p-type characteristics were exhibited, and from this, it could be confirmed that Zn₃As₂ nanocrystals synthesized according to the present invention inherently exhibited p-type characteristics.

### Experimental Example 11: Analysis of Electrical Characteristics of Zinc Halide-Exchanged Nanocrystals

Solution-phase ligand exchange was performed on Zn₃As₂ nanocrystals using ZnCl₂, ZnBr₂, and ZnI₂ as zinc halide-based inorganics, and electrical characteristics were evaluated for each nanocrystal.

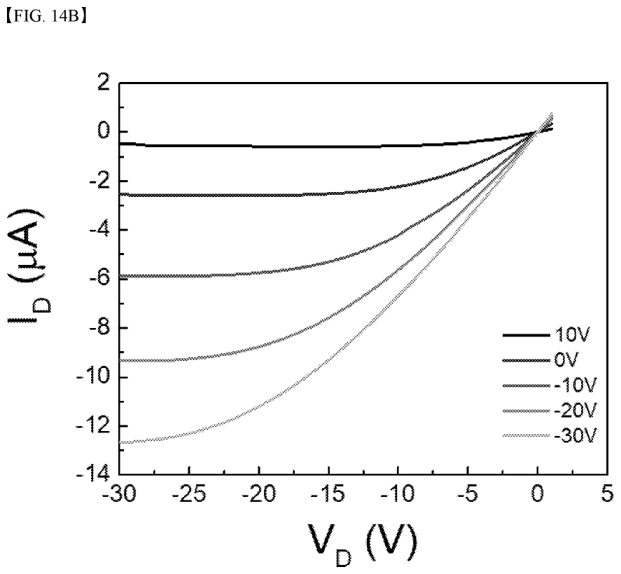

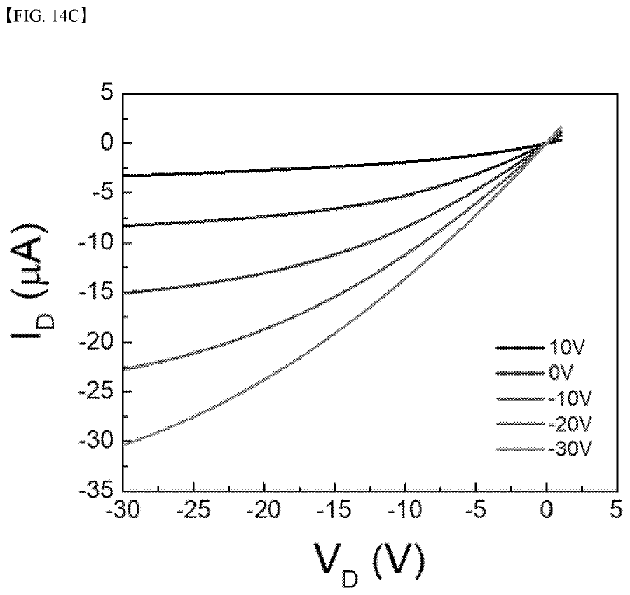

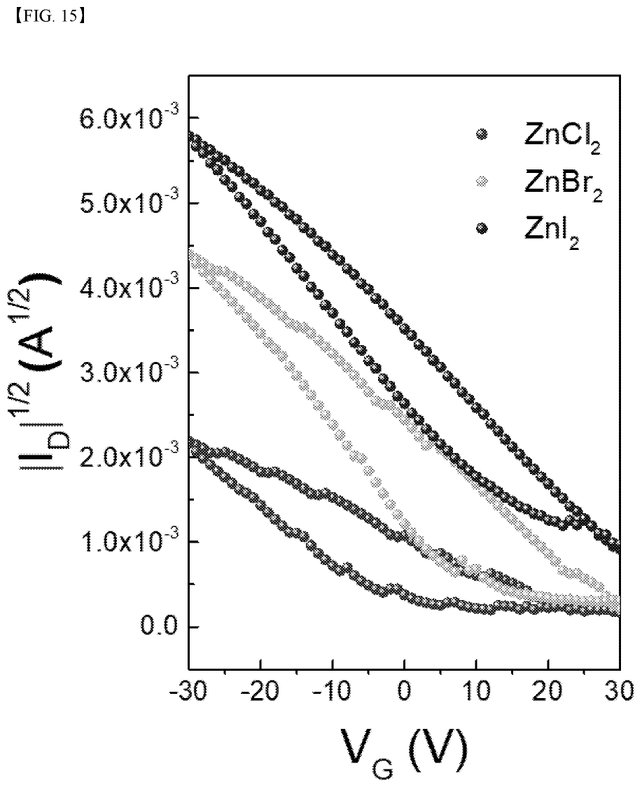

FIGS. 14A, 14B, and 14C show output electrical characteristic analysis results of nanocrystals exchanged using ZnCl₂ (A), ZnBr₂ (B), and ZnI₂ (C), respectively, and FIG. 15 shows transfer electrical characteristic analysis results of each nanocrystal.

For output characteristics of the ligand-exchanged nanocrystals, current increased as a size of the halide ions increased. In addition, when the nanocrystal thin films were treated with halide compounds, it was confirmed that hole mobility was improved in all of ZnCl₂, ZnBr₂, and ZnI₂.

Accordingly, it could be understood that electrical characteristics were improved when surfaces of the nanocrystals of the present invention were ligand-exchanged using a zinc halide.

While some embodiments of the present invention have been described above, the present invention is not limited only to the embodiments as described above, and may be carried out with modifications and variations within a range not departing from the gist of the present invention, and forms to which such modifications and variations are applied should also be understood to belong to the technical idea of the present invention.

What is claimed is:

1. A method for preparing an II-V group nanocrystal, comprising steps of:
preparing a precursor mixture by mixing a Group II precursor comprising a zinc halide and a Group V precursor comprising a halide of a Group V element; and
synthesizing a nanocrystal by adding a reducing agent to the precursor mixture and then performing a co-reduction reaction.

2. The method for preparing an II-V group nanocrystal according to claim 1,
wherein the zinc halide is at least one selected from the group consisting of zinc chloride (ZnCl₂), zinc iodide (ZnI₂), zinc fluoride (ZnF₂) and zinc bromide (ZnBr₂).

3. The method for preparing an II-V group nanocrystal according to claim 1,
wherein the halide of the Group V element is at least one selected from the group consisting of arsenic trichloride (AsCl₃), arsenic tribromide (AsBr₃), arsenic triiodide (AsI₃), antimony trichloride (SbCl₃), antimony tribromide (SbBr₃), antimony triiodide (SbI₃), phosphorus trichloride (PCl₃), phosphorus tribromide (PBr₃) and phosphorus triiodide (PI₃).

4. The method for preparing an II-V group nanocrystal according to claim 1,
wherein the Group II precursor and the Group V precursor each independently further comprise at least one ligand selected from the group consisting of a phosphine-based compound and an amine-based compound.

5. The method for preparing an II-V group nanocrystal according to claim 1,
wherein, in the precursor mixture, a molar ratio of zinc to the Group V element is 1:1 to 8:1.

6. The method for preparing an II-V group nanocrystal according to claim 1,
wherein the reducing agent comprises at least one selected from the group consisting of lithium triethylborohydride (superhydride), diisobutylaluminium hydride (DIBAL-H), lithium aluminium hydride (LiAlH₄), lithium borohydride (LiBH₄), sodium borohydride (NaBH₄), alane N,N-dimethylethylamine complex (DMEA-AlH₃) and tris(dimethylamino)phosphine.

7. The method for preparing an II-V group nanocrystal according to claim 1,
wherein the co-reduction reaction is performed at a temperature of 200 to 400°C.

8. The method for preparing an II-V group nanocrystal according to claim 1,
wherein the co-reduction reaction is performed for 10 to 120 minutes.

9. The method for preparing an II-V group nanocrystal according to claim 1,
further comprising, after the co-reduction step, a step of ligand-exchanging a surface of the nanocrystal by using a zinc halide solution.

10. The method for preparing an II-V group nanocrystal according to claim 9,
wherein the step of ligand-exchanging is performed by mixing the nanocrystal obtained through the co-reduction reaction with a zinc halide and vortexing.

11. The method for preparing an II-V group nanocrystal according to claim 1,
wherein an average particle diameter of the nanocrystal is 5 to 50 nm.

12. The method for preparing an II-V group nanocrystal according to claim 1,
wherein the II-V group nanocrystal is a Zn₃As₂ nanocrystal, a Zn₃P₂ nanocrystal or a Zn₃Sb₂ nanocrystal.

13. An II-V group nanocrystal prepared by the method according to claim 1.

14. The II-V group nanocrystal according to claim 13,
wherein the nanocrystal comprises a crystalline phase having a space group P4₂/nmc.

15. A field-effect transistor comprising an active layer formed using the II-V group nanocrystal according to claim 13.
